(19) United States
(12) Patent Application Publication
(10) Pub. No.: US 2026/0246863 A1
(43) Pub. Date: Aug. 20, 2026

(54) ELECTRONIC APPARATUS

(71) Applicant: Sony Group Corporation, Tokyo (JP)

(72) Inventors: Masaki NISHIO, Tokyo (JP); Michihiro KUNIGITA, Tokyo (JP)

(73) Assignee: Sony Group Corporation, Tokyo (JP)

(21) Appl. No.: 19/159,528

(22) PCT Filed: Feb. 6, 2024
(86) PCT No.: PCT/JP2024/003812

§ 371 Date: Aug. 25, 2025

(30) Foreign Application Priority Data
Mar. 22, 2023 (JP) 2023-044850

(51) Int. Cl. H04M 1/02; H05K 1/14

(52) U.S. Cl. CPC H04M 1/0274; H04M 1/0262; H05K 1/147

(57) ABSTRACT

An electronic apparatus includes a frame, a circuit board, a first component, and an FPC. The frame includes a support surface. The circuit board includes a facing mounting surface that faces the support surface. The first component is fixed to the support surface and adjacent to the circuit board across a gap in an in-plane direction of the facing mounting surface. A second component is mounted the FPC, and the FPC forms a connection path. Between the second component and the facing mounting surface, the connection path passes between the first component and the support surface, and protrudes, in the gap, toward a direction opposite to a direction of the support surface.

### TECHNICAL FIELD

The present technology relates to an electronic apparatus such as a smartphone.

### BACKGROUND ART

Patent Literature 1 discloses a technology used to make electronic apparatuses smaller in size.

### CITATION LIST

### Patent Literature

Patent Literature 1: Japanese Patent Application Laid-open No. 2007-193961

### DISCLOSURE OF INVENTION

### Technical Problem

It is more difficult to secure mounting spaces of electronic apparatuses if the electronic apparatuses are made smaller in size. Further, if electronic apparatuses are made smaller in size, constraints on a degree of freedom in design are more easily added due to various factors such as assembling properties.

In view of the circumstances described above, it is an object of the present technology to increase a degree of freedom in a design of an electronic apparatus.

### Solution to Problem

In order to achieve the object described above, an electronic apparatus according to an embodiment of the present technology includes a frame, a circuit board, a first component, and an FPC.

The frame includes a support surface.

The circuit board includes a facing mounting surface that faces the support surface.

The first component is fixed to the support surface and adjacent to the circuit board across a gap in an in-plane direction of the facing mounting surface.

A second component is mounted the FPC, and the FPC forms a connection path. Between the second component and the facing mounting surface, the connection path passes between the first component and the support surface, and protrudes, in the gap, toward a direction opposite to a direction of the support surface.

In this electronic apparatus, the FPC is connected to the facing mounting surface being included in the circuit board and facing the frame. It is often the case that a CPU that generates heat when being driven is mounted on the facing mounting surface situated close to the frame. In this regard, this electronic apparatus makes it possible to connect the CPU and the FPC on a single mounting surface. This results in being less likely to cause a loss in a mounting space.

On the other hand, when the FPC is connected to the facing mounting surface situated close to the frame, the frame is obstructive upon performing rework with attachment of the FPC to and removal of the FPC from the facing mounting surface. Thus, it is necessary that, upon such rework, the circuit board be removed from the frame to separate the facing mounting surface from the frame and a pose of the circuit board be changed to be suitable.

In this regard, a protrusion is provided in a gap situated between the first component and the circuit board in the FPC of the electronic apparatus. This results in securing an extra length between the first component and the circuit board. Thus, in the electronic apparatus, a pose of the circuit board removed from the frame can be changed with a high degree of freedom without removing the first component from the frame.

The first component may be a secondary battery.

The electronic apparatus may further include a CPU that is mounted on the facing mounting surface.

The second component may be a USB connector.

The electronic apparatus may further include a board-to-board connector that connects the FPC and the facing mounting surface.

The circuit board may further include a first substrate that is included in the facing mounting surface, a second substrate that faces the first component on an opposite side of the first component from the support surface, and a connection substrate that forms a space between the first substrate and the second substrate, the connection substrate connecting the first substrate and the second substrate.

The connection substrate may be an interposer substrate.

### BRIEF DESCRIPTION OF DRAWINGS

FIG. 1 is a perspective view of an electronic apparatus according to an embodiment of the present technology.

FIG. 2 schematically illustrates a partial cross-sectional view of the electronic apparatus according to the embodiment along the line A-A′ of FIG. 1.

FIG. 3 is a partial cross-sectional view of an electronic apparatus according to a first comparative example.

FIG. 4 is a partial cross-sectional view of an electronic apparatus according to a second comparative example.

FIG. 5 illustrates an operation performed by the electronic apparatus according to the embodiment upon performing rework.

### MODE(S) FOR CARRYING OUT THE INVENTION

An embodiment of the present technology is described in detail below with reference to the drawings.

### Overall Configuration

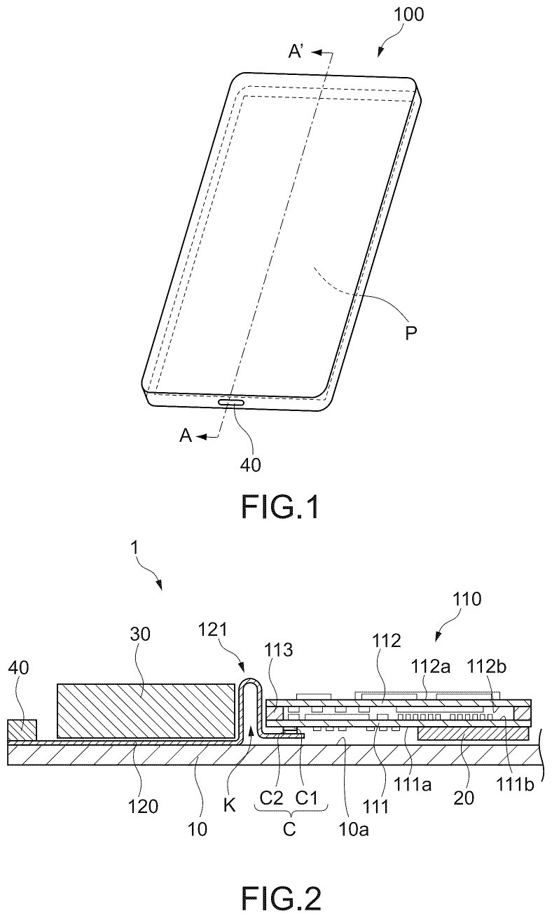

FIG. 1 is a perspective view of an electronic apparatus 1 according to the present embodiment. The electronic apparatus 1 illustrated in FIG. 1 is a smartphone that is a multifunctional mobile terminal apparatus including a call function. FIG. 1 illustrates a back surface of the electronic apparatus 1 that is provided with a rear panel. The electronic apparatus 1 includes a touchscreen display P on a front surface of the electronic apparatus 1 that is provided with a front panel, as indicated using a dashed line in FIG. 1.

FIG. 2 schematically illustrates a partial cross section that is a portion of a cross section of the electronic apparatus 1 along the line A-A′ of FIG. 1. The electronic apparatus 1 further includes a frame 10. The frame 10 is a support member that supports respective structural elements built in the electronic apparatus 1. The frame 10 is formed using a material having a high mechanical strength and providing an excellent heat-release performance, and is favorably formed using a metallic material.

The frame 10 is provided with a support surface 10a that is oriented toward the rear panel (the back surface) of the electronic apparatus 1. A form of the support surface 10a of the frame 10 is not particularly limited, and the support surface 10a may be, for example, flat, curved, or uneven. Note that the electronic apparatus 1 may be configured such that the support surface 10a of the frame 10 is oriented toward the front panel (the front surface).

The electronic apparatus 1 further includes a circuit board 110. The circuit board 110 has a three-layer structure including a first substrate 111, a second substrate 112, and a connection substrate 113. In the circuit board 110, the first substrate 111 and the second substrate 112 are arranged to face each other, and the connection substrate 113 is arranged between the first substrate 111 and the second substrate 112.

The circuit board 110 includes four mounting surfaces, and specifically, the circuit board 110 includes a facing mounting surface 111a and an inner mounting surface 111b that are provided to the first substrate 111 as well as an open mounting surface 112a and an inner mounting surface 112b that are provided to the second substrate 112. In the circuit board 110, the inner mounting surface 111b of the first substrate 111 and the inner mounting surface 112b of the second substrate 112 face each other.

In the circuit board 110, the first substrate 111 is situated on the side of the frame 10, that is, the facing mounting surface 11la of the first substrate 111 faces the support surface 10a of the frame 10. Further, in the circuit board 110, the open mounting surface 112a of the second substrate 112 is oriented in a direction opposite to a direction of the support surface 10a of the frame 10.

The connection substrate 113 is partially arranged between the first substrate 111 and the second substrate 112 to form a space between the first substrate 111 and the second substrate 112. This makes it possible to use, as mounting spaces, regions that are respectively included in the inner mounting surfaces 111b and 112b in the circuit board 110 and in which the connection substrate 113 is not arranged.

Further, the connection substrate 113 includes a function to connect the first substrate 111 and the second substrate 112 electrically. For example, a large number of metallic pins that pass through the connection substrate 113 in a thickness direction of the connection substrate 113 to electrically connect the inner mounting surfaces 111b and 112b may be arranged in the connection substrate 113. Typically, the connection substrate 113 is an interposer substrate.

The electronic apparatus 1 further includes a central processing unit (CPU) 20. The CPU 20 performs, for example, various control processes and computational processes that are necessary to implement the functionality of the electronic apparatus 1. The CPU 20 is mounted on the facing mounting surface 111a being included in the circuit board 11 and facing the frame 10. Thus, the CPU 20 is situated close to the frame 10.

In the electronic apparatus 1, heat generated by the CPU 20 being driven can be diffused to the frame 10 having a high thermal conductivity and a large thermal capacity, since the CPU 20 is situated close to the frame 10. Accordingly, in the electronic apparatus 1, an effect of heat release from the CPU 20 that is provided by the frame 10 can be obtained, and thus a decrease in performance that is caused due to overheat of the CPU 20 can be prevented.

The electronic apparatus 1 further includes a secondary battery 30 as a first component. The secondary battery 30 is chargeable from an external power supply, and stores therein electrical energy necessary to drive the electronic apparatus 1. The secondary battery 30 is connected to various structural elements built in the electronic apparatus 1, and supplies the electrical energy to these components. Typically, the secondary battery 30 is a lithium-ion secondary battery. In addition to this, the secondary battery 30 may be, for example, a nickel hydrogen battery or a lithium polymer battery.

The secondary battery 30 is arranged adjacently to the circuit board 110 in an in-plane direction of the facing mounting surface 111a, and is fixed to the support surface 10a of the frame 10 using, for example, bonding paper. In the electronic apparatus 1, a gap K is formed between the secondary battery 30 and the circuit board 110 in the in-plane direction of the facing mounting surface 111a included in the circuit board 110.

From the standpoint of mounting space saving, it is desirable that the gap K be narrow in the electronic apparatus 1. On the other hand, from the standpoint of securing of a space in which a protrusion 121 of an FPC 120 described later is arranged, it is not desirable that the gap K be too narrow in the electronic apparatus 1.

The electronic apparatus 1 further includes a Universal-Serial-Bus (USB) connector 40 as a second component. As illustrated in FIG. 1, the USB connector 40 is exposed from an outer surface of the electronic apparatus 1, and is a component used to receive connection of a USB terminal by the USB terminal being externally inserted into the USB connector 40. On the support surface 10a of the frame 10, the USB connector 40 is situated across the secondary battery 30 from the circuit board 110.

The USB connector 40 is electrically connected to various structural elements including the circuit board 110 and secondary battery 30 built in the electronic apparatus 1. As a result, input and output of various signals that are performed between an external apparatus and the CPU 20, and charging of the secondary battery 30 from an external power supply can be performed through the USB connector 40 in the electronic apparatus 1.

The electronic apparatus 1 further includes a flexible printed circuit (FPC) 120. The FPC 120 is a film circuit board formed using a highly flexible material. The FPC 120 is a USB board on which the USB connector 40 is mounted, and, through the FPC 120, the USB connector 40 is electrically connected to various substrates including the circuit board 110 built in the electronic apparatus 1.

On the facing mounting surface 111a, the FPC 120 is connected to the circuit board 110. Between the USB connector 40 and the facing mounting surface 111a of the circuit board 110, the FPC 120 forms a connection path that passes between the support surface 10a of the frame 10 and the secondary battery 30 and that passes through the gap K situated between the secondary battery 30 and the circuit board 110.

Further, in the gap K situated between the secondary battery 30 and the circuit board 110, the FPC 120 includes the protrusion 121 protruding toward a direction opposite to a direction of the support surface 10a of the frame 10. In other words, the protrusion 121 of the FPC 120 forms, in the gap K situated between the secondary battery 30 and the circuit board 110, a detour of taking a long way in the direction opposite to the direction of the support surface 10a of the frame 10.

The protrusion 121 is provided between the secondary battery 30 and the circuit board 110 in order to secure an extra length of the FPC 120. From this standpoint, it is desirable that the protrusion 121 have a height, from the support surface 10a of the frame 10, that exhibits a value larger than a value obtained by dividing, by two, a sum of a height of the secondary battery 30 and a thickness of the circuit board 110. Further, it is sufficient if the protrusion 121 enters the gap K, and a shape of a cross section of the protrusion 121 is not particularly limited.

The electronic apparatus 1 further includes a connection section C. The connection section C includes a removable pair of a first terminal C1 and a second terminal C2. The first terminal C1 of the connection section C is provided to the facing mounting surface 111a of the circuit board 110. The second terminal C2 of the connection section C is provided to the FPC 120. Typically, the connection section C is a board-to-board (B-to-B) connector.

In the electronic apparatus 1, the second terminal C2 is attached to the first terminal C1, and this enables the FPC 120 to be electrically connected to the facing mounting surface 111a of the circuit board 110 concurrently with fixation of the FPC 120 to the facing mounting surface 111a. This enables the FPC 120 to be easily and certainly connected to the facing mounting surface 111a of the circuit board 110 in the electronic apparatus 1.

### Actions and Effects

In the electronic apparatus 1, the FPC 120 is connected to the facing mounting surface 111a of the circuit board 110, and the connection section C connecting the FPC 120 and the circuit board 110, and the CPU 20 are both situated on the facing mounting surface 111a. Thus, in the electronic apparatus 1, the FPC 120 and the CPU 20 can be electrically connected to each other only using wiring on the facing mounting surface 111a of the circuit board 110.

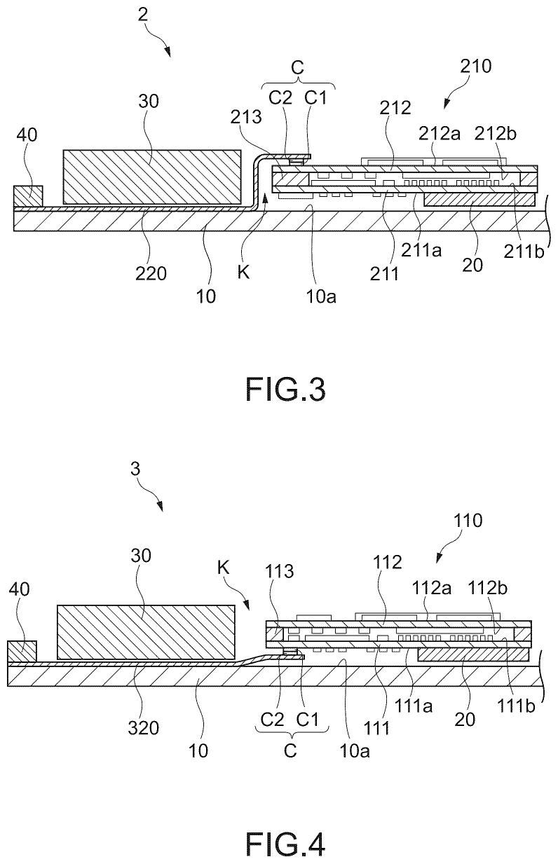

FIG. 3 is a partial cross-sectional view of an electronic apparatus 2 according to a first comparative example of the present technology. A circuit board 210 and an FPC 220 that are included in the electronic apparatus 2 according to the first comparative example respectively have different configurations than the circuit board 110 and FPC 120 according to the embodiment described above. In FIG. 3, a structural element of the electronic apparatus 2 according to the first comparative example that is the same as the structural element of the electronic apparatus 1 according to the present embodiment is denoted by the same reference numeral as the electronic apparatus 1 according to the present embodiment.

The electronic apparatus 2 is manufactured in a typical process in which the FPC 220 is connected to the circuit board 210 assembled to the support surface 10a of the frame 10. Thus, in the electronic apparatus 2, the connection section C used to connect the FPC 220 to the circuit board 210 is provided on an open mounting surface 212a that is not closed with the frame 10.

In the circuit board 210, it is necessary that the connection section C provided to the open mounting surface 212a be electrically connected to a facing mounting surface 211a, in order to electrically connect the FPC 220 connected to the open mounting surface 212a and the CPU 20 mounted on the facing mounting surface 211a. Thus, in the circuit board 210, there is a need to extend a connection substrate 213 according to a position of the connection section C.

In the circuit board 210 according to the first comparative example, mounting spaces on inner mounting surfaces 211b and 212b are respectively reduced as the connection substrate 213 is extended. In other words, in the electronic apparatus 1 according to the present embodiment, the connection substrate 113 can be made smaller in size, compared to the connection substrate 213 of the electronic apparatus 2 according to the first comparative example. This makes it possible to secure a larger mounting space.

Further, FIG. 4 is a partial cross-sectional view of an electronic apparatus 3 according to a second comparative example of the present technology. An FPC 320 that is included in the electronic apparatus 3 according to the second comparative example has a different configuration than the FPC 120 according to the embodiment described above. In FIG. 4, a structural element of the electronic apparatus 3 according to the second comparative example that is the same as the structural element of the electronic apparatus 1 according to the present embodiment is denoted by the same reference numeral as the electronic apparatus 1 according to the present embodiment.

The FPC 320 according to the second comparative example is similar to the FPC 120 according to the present embodiment in being connected to the circuit board 110 on the facing mounting surface 111a. The FPC 320 connects the USB connector 40 and the facing mounting surface 111a of the circuit board 110 substantially in the shortest distance, and forms a connection path advantageous from the viewpoint of connection efficacy to which importance is attached generally.

In both the electronic apparatus 1 according to the present embodiment and the electronic apparatus 3 according to the second comparative example, the facing mounting surface 111a provided with the connection section C connecting the FPC 120, 320 and the circuit board 110 is closed with the frame 10. Thus, in the electronic apparatuses 1 and 3, the frame 10 is obstructive upon performing rework with attachment of the FPC 120, 320 to and removal of the FPC 120, 320 from the facing mounting surface 111a of the circuit board 110.

With respect to the rework with attachment of the FPC 120, 320 to and removal of the FPC 120, 320 from the facing mounting surface 111a of the circuit board 110, examples of the rework, which may be necessary for the electronic apparatus 1, 3, include replacement with a new circuit board 110 due to a failure in the circuit board 110, and resolving of a failure in connection of the FPC 120, 320 to the circuit board 110.

In each of the electronic apparatuses 1 and 3, it is necessary that, upon such rework, the circuit board 110 be removed from the frame 10 to separate the facing mounting surface 111a from the frame 10. Further, in each of the electronic apparatuses 1 and 3, there is a need to change a pose of the circuit board 110 removed from the frame 10 such that the facing mounting surface 111a is oriented toward a direction suitable for such rework.

In the electronic apparatus 3 according to the second comparative example, movement of the circuit board 110 removed from the frame 10 is restricted by the secondary battery 30 confining the FPC 320 to the support surface 10a of the frame 10. Thus, in the electronic apparatus 3, there is a need to remove the secondary battery 30 from the support surface 10a of the frame 10 in order to change the pose of the circuit board 110 to a pose suitable for rework.

It is difficult to reuse the secondary battery 30 when once removed from the frame 10, due to, for example, occurrence of wrinkles. Thus, in the electronic apparatus 3 according to the second comparative example, there is a need to throw away the secondary battery 30 removed from the frame 10 and to provide a new secondary battery 30. In other words, it costs a lot to replace the secondary battery 30 every time rework is performed.

On the other hand, in the electronic apparatus 1 according to the present embodiment, the FPC 120 has a configuration in which the protrusion 121 is intendedly provided between the secondary battery 30 and the circuit board 110, which is disadvantageous from the viewpoint of connection efficacy. This results in securing an extra length between the circuit board 110 removed from the frame 10 and the secondary battery 30 in the electronic apparatus 1.

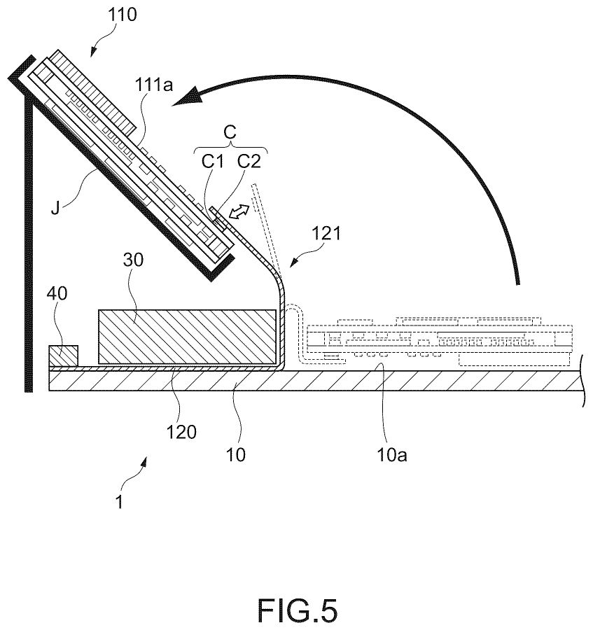

FIG. 5 illustrates an operation performed by the electronic apparatus 1 upon performing rework with attachment of the FPC 120 to and removal of the FPC 120 from the facing mounting surface 111a of the circuit board 110. FIG. 5 illustrates a jig J that can hold the circuit board 110 above the secondary battery 30 when recork is performed in the electronic apparatus 1, the circuit board 110 being in a state in which the facing mounting surface 111a is open.

In the FPC 120, the provision of the protrusion 121 between the secondary battery 30 and the circuit board 110 results in a region situated between the circuit board 110 removed from the frame 10 and the secondary battery 30 having a sufficient length. Thus, in the electronic apparatus 1, the circuit board 110 can be placed on the jig J without removing the secondary battery 30 from the frame 10.

In other words, the circuit board 110 placed on the jig J is in a pose in which the facing mounting surface 111a is oriented diagonally upward, as illustrated in FIG. 5, which is suitable for rework. This makes it possible to easily attach the second terminal C2 to and remove the second terminal C2 from the first terminal C1 in the electronic apparatus 1 illustrated in FIG. 5, where the second terminal C2 is provided to the FPC 120 and the first terminal C1 is provided to the facing mounting surface 111a of the circuit board 110.

As described above, the technology according to the present embodiment makes it possible to adopt a configuration in which the FPC 120 is connected to the circuit board 110 on the facing mounting surface 111a without constraints of an increase in costs that is caused due to replacement of the secondary battery 30 upon performing rework. Thus, the technology according to the present embodiment technology enables an increase in a degree of freedom in design of the electronic apparatus.

### Other Embodiments

The embodiments of the present technology have been described above. However, the present technology is not limited to the embodiments described above, and various modifications may be made thereto without departing from the scope of the present technology.

For example, it is sufficient if the circuit board of the electronic apparatus according to the present technology includes a facing mounting surface that faces a frame, and the circuit board of the electronic apparatus according to the present technology is not limited to the above-described configuration including the first substrate 111, the second substrate 112, and the connection substrate 113. For example, the circuit board according to the present technology may be a single-layer board that only includes, as mounting surfaces, a facing mounting surface and an open mounting surface.

Further, it is sufficient if a first component of the electronic apparatus according to the present technology is fixed to a support surface of a frame and adjacent to a circuit board across a gap in an in-plane direction of a facing mounting surface. The first component is not limited to the secondary battery 30. The present technology is especially effective when a component that will be difficult to be reused if the component is removed from a frame, is used as the first component, as in the case of the secondary battery 30.

Further, it is sufficient if a second component of the electronic apparatus according to the present technology is a component that is mounted on an FPC and necessary to be connected to the facing mounting surface included in the circuit board. The second component is not limited to the USB connector 40. Furthermore, it is sufficient if the second component according to the present technology is situated on the support surface of the frame. The second component is not limited to being situated across the first component from the circuit board.

In addition, in the electronic apparatus according to the present technology, greater effects are provided by a CPU being mounted on the facing mounting surface included in the circuit board. However, a position of the CPU can be changed discretionarily. In this case, in the electronic apparatus according to the present technology, the effects described above are also provided by the second component and the facing mounting surface included in the circuit board being connected to each other through the FPC.

Further, it is sufficient if the FPC and the circuit board can be connected to each other through the connection section C in the electronic apparatus according to the present technology. The connection section C is not limited to including the first terminal and the second terminal, as described above. In the electronic apparatus according to the present technology, for example, the FPC and the circuit board may be directly joined to each other at a portion corresponding to the connection section C without using connector components.

Moreover, the configuration of the present technology is effective for various electronic apparatuses in addition to smartphones, and is especially effective for a mobile electronic apparatus for which there is a strong need for a smaller size and a higher performance. Examples of the mobile electronic apparatus other than a smartphone include a tablet terminal, a portable media player, a portable game machine, an e-book reader, and a wearable device.

Note that the present technology may also take the following configurations.

(1) An electronic apparatus, including:
a frame that includes a support surface;
a circuit board that includes a facing mounting surface that faces the support surface;
a first component that is fixed to the support surface and adjacent to the circuit board across a gap in an in-plane direction of the facing mounting surface; and
an FPC on which a second component is mounted, the FPC forming a connection path, in which
between the second component and the facing mounting surface, the connection path passes between the first component and the support surface, and protrudes, in the gap, toward a direction opposite to a direction of the support surface.

(2) The electronic apparatus according to (1), in which
the first component is a secondary battery.

(3) The electronic apparatus according to (1) or (2), further including
a CPU that is mounted on the facing mounting surface.

(4) The electronic apparatus according to any one of (1) to (3), in which
the second component is a USB connector.

(5) The electronic apparatus according to any one of (1) to (4), further including
a board-to-board connector that connects the FPC and the facing mounting surface.

(6) The electronic apparatus according to any one of (1) to (5), in which
the circuit board further includes
   a first substrate that is included in the facing mounting surface,
   a second substrate that faces the first component on an opposite side of the first component from the support surface, and
   a connection substrate that forms a space between the first substrate and the second substrate, the connection substrate connecting the first substrate and the second substrate.

(7) The electronic apparatus according to (6), in which
the connection substrate is an interposer substrate.

### REFERENCE SIGNS LIST

1 electronic apparatus
10 frame
10a support surface
20 CPU
30 secondary battery
40 USB connector
110 circuit board
111 first substrate
111a facing mounting surface
111b inner mounting surface
112 second substrate
112a open mounting surface
112b inner mounting surface
113 connection substrate
120 FPC
121 protrusion
C connection section
C1 first terminal
C2 second terminal
K gap

1. An electronic apparatus, comprising:
a frame that includes a support surface;
a circuit board that includes a facing mounting surface that faces the support surface;
a first component that is fixed to the support surface and adjacent to the circuit board across a gap in an in-plane direction of the facing mounting surface; and
an FPC on which a second component is mounted, the FPC forming a connection path, wherein
between the second component and the facing mounting surface, the connection path passes between the first component and the support surface, and protrudes, in the gap, toward a direction opposite to a direction of the support surface.

2. The electronic apparatus according to claim 1, wherein
the first component is a secondary battery.

3. The electronic apparatus according to claim 1, further comprising
a CPU that is mounted on the facing mounting surface.

4. The electronic apparatus according to claim 1, wherein
the second component is a USB connector.

5. The electronic apparatus according to claim 1, further comprising
a board-to-board connector that connects the FPC and the facing mounting surface.

6. The electronic apparatus according to claim 1, wherein
the circuit board further includes
a first substrate that is included in the facing mounting surface,
a second substrate that faces the first component on an opposite side of the first component from the support surface, and
a connection substrate that forms a space between the first substrate and the second substrate, the connection substrate connecting the first substrate and the second substrate.

7. The electronic apparatus according to claim 6, wherein
the connection substrate is an interposer substrate.
